(19) United States
(12) Patent Application Publication
(10) Pub. No.: US 2009/0045423 A1
(43) Pub. Date: Feb. 19, 2009

(54) SEMICONDUCTOR LIGHT-EMITTING DEVICE

(76) Inventors: Takashi Hashimoto, Chiba (JP); Takaki Yasuda, Chiba (JP)

Correspondence Address: SUGHRUE MION, PLLC, 2100 PENNSYLVANIA AVENUE, N.W., SUITE 800, WASHINGTON, DC, 20037, US

(21) Appl. No.: 12/159,919

(22) PCT Filed: Dec. 27, 2006
(86) PCT No.: PCT/JP2006/326366

§ 371 Date: Jul. 2, 2008

Related U.S. Application Data
(60) Provisional application No. 60/758,564, filed on Jan. 13, 2006.
(60) Provisional application No. 60/758,564, filed on Jan. 13, 2006.

(51) Int. Cl. H01L 33/00

(52) U.S. Cl. 257/98; 257/E33.068

(57) ABSTRACT

An object of the present invention is to provide a light-emitting device with a high output and a high efficiency by improving the efficiency for utilizing light emitted from a semiconductor light-emitting element.

The inventive semiconductor light-emitting device comprises a package substrate, a sub-mount provided on the package substrate, a semiconductor light-emitting element provided on the sub-mount, and a reflector surrounding the sub-mount and the semiconductor light-emitting element, wherein the positions and sizes of the sub-mount, light-emitting element and reflector satisfy the following relationship (A) on a cross section perpendicular to the package substrate that passes through the center of the semiconductor light-emitting element,

r−1s≦(hs−d)×(1s−1c)/hc (A)
wherein r, 1s and 1c are distances from the drooping portion of the reflector, from the outer circumference of the sub-mount and from the outer circumference of the semiconductor light-emitting element to the center of the semiconductor light-emitting element, respectively, hs and d are heights of the sub-mount and of the drooping portion of the reflector, respectively, and hc is a height of the upper surface of the semiconductor light-emitting element from the upper surface of the sub-mount.

### CROSS REFERENCE TO RELATED APPLICATION

This application is an application filed under 35 U.S.C. §111(a) claiming benefit, pursuant to 35 U.S.C. §119(e)(1), of the filing date of the Provisional Application No. 60/758,564 filed on Jan. 13, 2006, pursuant to 35 U.S.C. §111(b).

### TECHNICAL FIELD

This invention relates to a semiconductor light-emitting device. More specifically, the invention relates to a semiconductor light-emitting device having a reflector surrounding a semiconductor light-emitting element.

### BACKGROUND ART

The trend toward higher outputs and higher efficiencies of LEDs is also expanding their field of applications. In addition to the traditional uses as indicators and large outdoor display, which are colored, the LEDs are finding rapidly expanding fields of use as sources of back lights for cell phones, headlights and sources of illumination which emit white light. Attempts to meet such needs require a further increase in the output and efficiency.

The LED chips can be roughly divided into those of the type forming an LED epitaxial stacked-layer structure on a general electrically conducting substrate used by the LEDs, of the As-type, and those of the type forming the LED epitaxial stacked-layer structure on the insulating substrate much used by the LEDs, of the N-type. In the LED chips of the former type, electrodes are formed on the front surface of the semiconductor and on the back surface of the substrate, i.e. the upper electrode is formed on the top surface of LED chip and the lower electrode is formed on the bottom surface of LED chip, while in the LED chips of the latter type, two electrodes are formed on the surface of the semiconductor. An example of mounting a chip having upper and lower electrodes formed on the top and bottom surfaces of LED chip has been taught in Japanese Unexamined Patent Publication No. 61-77347, and an example of mounting a chip having two electrodes formed on the semiconductor surface has been disclosed in, for example, Japanese Unexamined Patent Publication No. 5-243613. There further exist a chip of the face-up type in which the substrate surface serves as a mounting surface and a chip of the flip-chip type in which the semiconductor surface serves as a mounting surface. There further exists an art according to which a chip of the flip-chip type is bonded to a member, called a sub-mount, of a size larger than the chip via Au bumps enabling wire bonding like the face-up chip (see, for example, Japanese Patent No. 3257455).

The sub-mount has heretofore been used for accomplishing the electric junction or as a protection circuit against the electrostatic breakdown, but has not been used for enhancing the efficiency for utilizing light emitted from a semiconductor light-emitting element. Concerning its size, the sub-mount has a size equal to that of an LED chip or has a size increased by an area of wire bonding pads, generally.

Further, a semiconductor light-emitting device with a reflector has heretofore been known (see, for example, FIG. 1 of Japanese Unexamined Patent Publication No. 2003-8074). In practically perforating the reflector, the opening portion in the bottom surface droops in a thickness of about 100 μm as shown in FIG. 6, and part of light emitted from the semiconductor light-emitting element falls on the non-reflecting surfaces of the drooping portion (5) of the reflector and of the package substrate surface (7); i.e., light is not effectively utilized accounting for a poor light utilization efficiency.

Further, a semiconductor light-emitting device using a reflector of a parabolic surface has heretofore been known (see, for example, FIG. 1 of Japanese Unexamined Patent Publication No. 58-164276). If the focal point is a semiconductor light-emitting element, the reflector must have a large opening portion. Similarly, therefore, part of light emitted from the semiconductor light-emitting element falls on the non-reflecting surfaces of the drooping portion (5) of the reflector and of the package substrate surface (7); i.e., light is not effectively utilized accounting for a poor light utilization efficiency.

That is, in the semiconductor light-emitting device having a reflector attached onto the mounting surface of the package substrate at a subsequent step, the opening portion in the bottom surface of the reflector inevitably droops in a thickness of about 100 μm. On the other hand, the light-emitting element chip, usually, has a thickness of 50 μm to 500 μm. In the conventional LED package to which the reflector is attached at a subsequent step, therefore, the drooping portion faces the chip in the horizontal direction, and the ray of light is not controlled as optically designed. Besides, the stray ray of light is repetitively reflected between the chip and the package substrate and attenuates causing the loss of light and decreasing the efficiency.

### DISCLOSURE OF THE INVENTION

An object of the present invention is to solve the above-mentioned problems inherent in the semiconductor light-emitting devices with the reflector and to provide a light-emitting device of a high output and a high efficiency by improving the efficiency for utilizing light emitted from a semiconductor light-emitting element.

The present invention provides the following device.

(1) A semiconductor light-emitting device comprising a package substrate, a sub-mount provided on the package substrate, a semiconductor light-emitting element provided on the sub-mount, and a reflector surrounding the sub-mount and the semiconductor light-emitting element, wherein the positions and sizes of the sub-mount, light-emitting element and reflector satisfy the following relationship (A) on a cross section perpendicular to the package substrate that passes through the center of the semiconductor light-emitting element,

r−1s≦(hs−d)×(1s−1c)/hc (A)
wherein r, 1s and 1c are distances from the drooping portion of the reflector, from the outer circumference of the sub-mount and from the outer circumference of the semiconductor light-emitting element to the center of the semiconductor light-emitting element, respectively, hs and d are heights of the sub-mount and of the drooping portion of the reflector, respectively, and hc is a height of the upper surface of the semiconductor light-emitting element from the upper surface of the sub-mount.

(2) The semiconductor light-emitting device according to (1) above, wherein the side surface of the reflector is a parabolic surface, and its focal point is a center of the semiconductor light-emitting element.

(3) The semiconductor light-emitting device according to (1) or (2) above, wherein the semiconductor light-emitting element is of the face-up type.

(4) The semiconductor light-emitting device according to (1) or (2) above, wherein the semiconductor light-emitting element is of the type having upper and lower electrodes on the top and bottom surfaces of the element.

This invention provides a light-emitting device of a high output improving the efficiency for taking out the light of the semiconductor light-emitting device equipped with a reflector. In designing the reflector, further, the diameter of the reflector and the height of the reflector can be freely designed by varying the height of the sub-mount for the semiconductor light-emitting element while maintaining the light-emitting efficiency. This makes it possible to increase an efficiency and a output, as for a indicator and a large outdoor display, which are colored, and a source of back light for cell phones, a headlight and a source of light for illumination which emit white light.

Upon matching the sizes and shapes of the sub-mount and the package, further, the loss of light can be minimized. The invention makes it possible to increase the output and efficiency of the light-emitting device irrespective of its size. Not being limited to infrared to ultraviolet monochromatic light-emitting elements of short wavelengths, it is possible to provide white LEDs and colored LEDs of high outputs and high efficiencies by using the semiconductor light-emitting element as a source of excitation and by adding substances for varying wavelengths.

### BRIEF DESCRIPTION OF THE DRAWINGS

FIG. 1 is a sectional view schematically illustrating a semiconductor light-emitting device fabricated in Example 1.

FIG. 2 is a plan view schematically illustrating the semiconductor light-emitting device fabricated in Example 1.

FIG. 3 is a plan view schematically illustrating the semiconductor light-emitting device of the invention using a rectangular semiconductor light-emitting element.

FIG. 4 is a plan view schematically illustrating the semiconductor light-emitting device of the invention using a polygonal semiconductor light-emitting element.

FIG. 5 is a plan view schematically illustrating the semiconductor light-emitting device of the invention using an elliptic reflector.

FIG. 6 is a sectional view schematically illustrating a conventional semiconductor light-emitting device with a reflector.

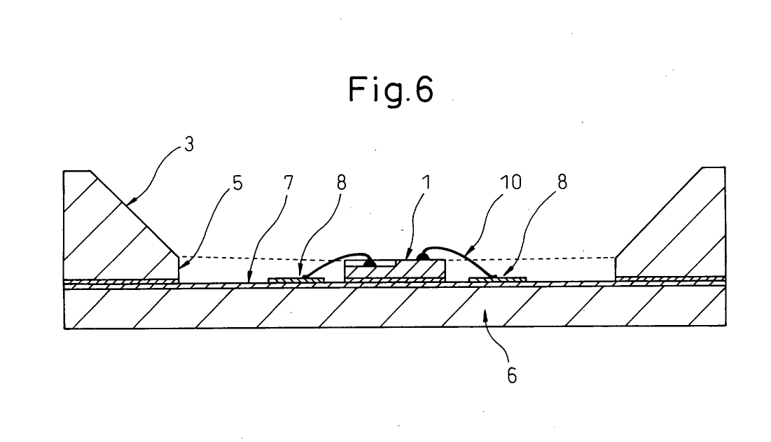

FIG. 7 is a sectional view schematically illustrating positional relationships of the semiconductor light-emitting device of the invention.

FIG. 8 is a sectional view schematically illustrating the semiconductor light-emitting device of the invention using a reflector of a parabolic surface.

FIG. 9 is a sectional view schematically illustrating the semiconductor light-emitting device fabricated in Example 2.

FIG. 10 is a sectional view schematically illustrating the semiconductor light-emitting device fabricated in Example 3.

### BEST MODE FOR CARRYING OUT THE INVENTION

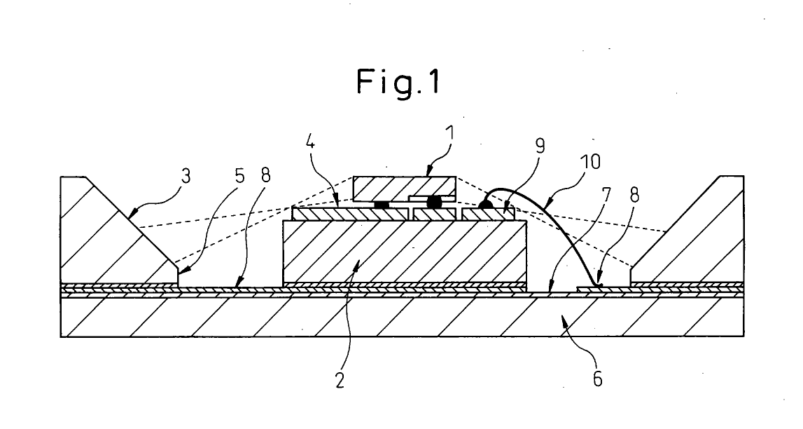

FIG. 1 is a view schematically showing in cross section a semiconductor light-emitting device of the present invention fabricated in Example 1 appearing later, and illustrates an ideal positional relationship of a chip (1), a sub-mount (2) and a reflector (3) preventing the light emitted from a semiconductor light-emitting element (1) from falling on the non-reflecting surfaces other than the reflection surfaces (3) of the reflector.

In order for the light from the semiconductor light-emitting element to fall on neither the package substrate surface (7) nor the drooping surface (5) of the reflector, it is important that the a and the b expressed by the following formulas,

a=r−1s

b=(hs−d)×(1s−1c)/hc

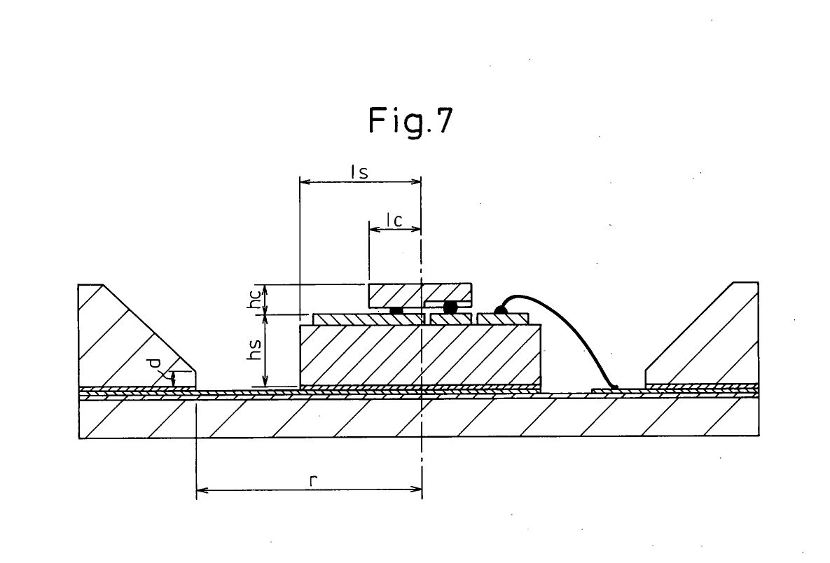

satisfy a relationship a≦b,
wherein, as shown in FIG. 7, r is a distance from the center of the semiconductor light-emitting element to the drooping portion of the reflector, is is a distance from the center of the semiconductor light-emitting element to the outer circumference of the sub-mount, 1c is a distance from the center of the semiconductor light-emitting element to the outer circumference of the semiconductor light-emitting element, hs is a height of the sub-mount, d is a height of the drooping portion, and hc is a height of the upper surface of the semiconductor light-emitting element from the upper surface of the sub-mount.

When the above relationship is satisfied, the light from the semiconductor light-emitting element falls on neither the package substrate surface nor the drooping surface of the reflector, and the light-emitting device features a high output and a high efficiency.

It is desired that the reflection surface of the reflector is of a parabolic surface and that the height of the sub-mount is so adjusted that the semiconductor light-emitting element becomes a focal point. It is further desired that the reflector surface is of a curved surface such as a spherical surface, a hyperboloid, a polynomial curved surface, a conical side surface or a cylindrical side surface, or a combination of such planes as a pyramidal side surface and a prismatic side surface. It is desired that the reflector is made of a metal or a resin and has its reflection surface optically treated. As the optical treatment, a metal is mirror-finished by polishing. As the diffusion finishing, the metal is grained, embossed or coated with a white coating material. Or, a resin provides mirror-reflection by being vacuum-coated with a reflecting metal film, or a resin containing a highly diffusing material is used. The reflecting metal film desirably contains Au, Ag, Ti, Ni, Cu, Cr, Al or Sn.

The sub-mount is desirably formed by using a semiconductor substrate such as silicon, GaP or GaAs, or a transparent substrate such as a glass or sapphire, from the standpoint of cost and flattening a portion for placing the chip. The sub-mount is often made of an electrically conducting material of a low resistance and in a shape in order to feed the electric power through the back surface of the sub-mount. Further, the sub-mount itself is often a semiconductor element such as a Zener diode so as to also serve as a circuit for protecting the LED chip.

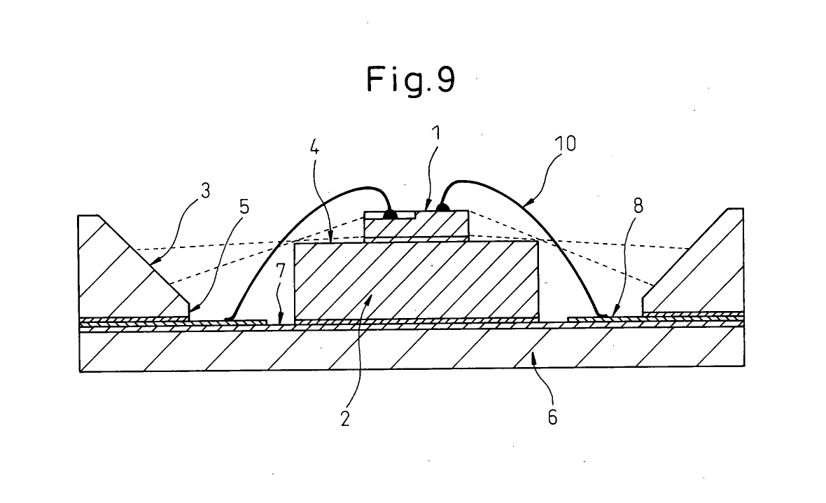

Referring, for example, to FIG. 9, when the two wires are connected to the electrodes on the LED chip surface and the ends on the other side of the wires are directly connected to the leads of the package substrate to supply the electric power, the sub-mount may be formed by using the structural member of a single material. Or, the bonding pads are often formed on the surface of the sub-mount in order to increase the bonding strength of the chip. Further, when the LED chip has the electrodes on the mounting surface, a wiring pattern is often formed on the surface of the sub-mount. In the case of the sub-mount for flip-chip, the electrode pads corresponding to the electrode arrangement of the chip and the electrode pattern to the external terminals, are formed on the surface of the sub-mount or in the inside thereof.

The sub-mount is usually formed in the shape of a square plate but is often formed in the shape of a polygonal plate such as a hexagonal plate, in the shape of a curved line such as a circular plate, or in the shape of a cubic block so as to also serve as a heat sink.

It is desired that the surface of the sub-mount, too, is optically treated. The optical treatment includes vacuum evaporation of a metal film, mirror finishing such as buffing, and diffusion finishing such as graining, embossing or coating with a white coating material. If the surface of the sub-mount is diffusion-finished, light diffuses on the surface of the sub-mount, and dispersion in the intensity decreases in the package.

The package substrate may often be of the type in which a metallic reflector is separately attached onto the printed board. The above-mentioned Japanese Unexamined Patent Publication No. 2003-8074 discloses a printed board using an insulating resin such as a glass-epoxy resin as a core with its both surfaces being covered with copper, wherein an electrode pattern is formed by etching the copper foil on the surface, and a metallic reflector such as of aluminum is adhered thereon with an insulating and adhesive film so as to surround the portion on where the LED chip is mounted. Instead of the substrate being covered with copper on both surfaces of a glass-epoxy resin core, there may be used a substrate having copper on one surface thereof, a substrate of a metal core with its both surfaces being covered with copper, a substrate of a metal core with its one surface being covered with copper, a substrate with its both surfaces being covered with copper having a ceramic such as alumina or aluminum nitride sandwiched therebetween, or a substrate with its both surfaces being covered with aluminum. These package substrates, usually, have a thickness of 0.1 mm to 10 mm.

The semiconductor light-emitting element is constituted by a III-V Group compound semiconductor of the As type, P type or N type, or by a II-VI Group compound semiconductor of the O type, S type or Se type. It is probable that the wavelength of the emitted light lies from a deep ultraviolet band of 200 nm up to an infrared band over 1 μm. Examples of the semiconductor light-emitting elements may include those of the face-up type in which the semiconductor layers are formed on an insulating substrate such as of sapphire, two electrodes are formed on the surface of the semiconductor layer and are electrically connected to the leads on the package substrate side or are electrically connected to the electrode patterns on the sub-mount through two wires, those of the flip-chip type in which the two electrodes are directly brought into contact with the electrode patterns on the sub-mount, and those of the type in which the semiconductor layers are formed on the electrically conducting substrate, one electrode is formed on the surface side of the semiconductor layers, another electrode is formed on the back surface side of the substrate, the electrode on the surface side of the semiconductor layers is connected to the lead on the package substrate side through a wire, and the back surface side of the substrate is adhered to the sub-mount via an electrically conducting adhesive to fix the chip and to conduct electricity. That is, the present invention exhibits the effect not only in the flip-chip but also in the face-up type semiconductor light-emitting element and the semiconductor light-emitting element of the type having an electrode on the back surface side of the substrate, which are not usually mounted on the sub-mount.

In the present invention, it is desired that the area of the drooping portion of the reflector, on where the light from the light-emitting element falls, is not larger than 50% if the whole circumferential area of the drooping portion of the reflector is 100%. More preferably, this area is not larger than 10% and, most preferably, this area is 0%. When 0%, the luminous intensity increases by about 10% on the parabolic axis of the semiconductor light-emitting device having the parabolic reflector as compared to the case of 80%.

### EXAMPLES

The invention will now be concretely described by way of Examples to which, however, the invention is in no way limited.

### Example 1

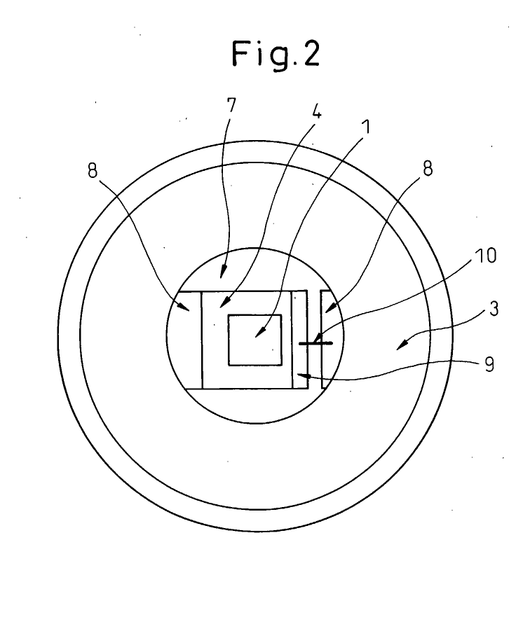

FIG. 1 is a sectional view schematically illustrating a semiconductor light-emitting device fabricated in this Example, and FIG. 2 is a schematic plan view thereof.

The semiconductor light-emitting element (1) was formed in a manner as described below. By using an MOCVD device, first, an epitaxially stacked layer structure of an LED comprising a III-Group nitride compound semiconductor was formed on a sapphire substrate. The surface of the above epitaxial wafer was patterned so as to form a light-emitting element of a square of 1 mm relying upon the photolithography technology, and the chip was partly engraved down to the n-type layer by dry etching. A negative electrode of the light-emitting element was formed on the etched portion and a positive electrode comprising a highly reflecting metal of the light-emitting element was formed on the surface that has not been etched. Thereafter, the back surface of the sapphire substrate was ground and polished to a thickness of about 80 μm, and the wafer was divided into 1-mm square chips of the flip-chip type.

The sub-mount (2) was obtained by forming an oxide layer on the surface of an n⁺-type Si wafer, and vacuum-evaporating Al (4) on the oxide layer in patterns corresponding to the patterns of the positive electrode and the negative electrode. The sub-mount was a 2-mm square having a height of 270 μm. The light-emitting element was a 1-mm square having a height of 80 μm.

The semiconductor blue light-emitting element of the flip-chip type formed as described above was mounted on the sub-mount for the semiconductor light-emitting element by using gold bumps. The sub-mount and the light-emitting elements were directed in the same direction and their centers were overlapped one upon the other. By using an electrically conducting adhesive, they were fixed onto an aluminum package substrate (6) of 50 mm×150 mm forming electrode patterns, and gold wires (10) of a diameter of 25 μm were bonded from the electrodes (9) on the sub-mount to the electrodes (8) on the package substrate.

An aluminum reflector (3) was coupled thereto with an adhesive. Here, the center of the light-emitting element was overlapped on the center of the reflector hole. The aluminum reflector was formed by machining a block of pure aluminum (a cylinder of a radius of 15 mm and a height of 10 mm). The side surface (reflection surface) (3) of the reflector was tapered in a conical shape at 45°. The reflector was mirror-finished on the reflection surface thereof, and possessed a hole of a diameter of 4 mm formed in the bottom portion thereof, and a height d of a drooping portion (5) (see FIG. 7) of 100 μm. The positional relationship was so designed as to satisfy the above formula (A).

The thus obtained semiconductor light-emitting device was evaluated for its light-emitting output. The whole emission flux was 160 mW when a forward current of 350 mA was supplied.

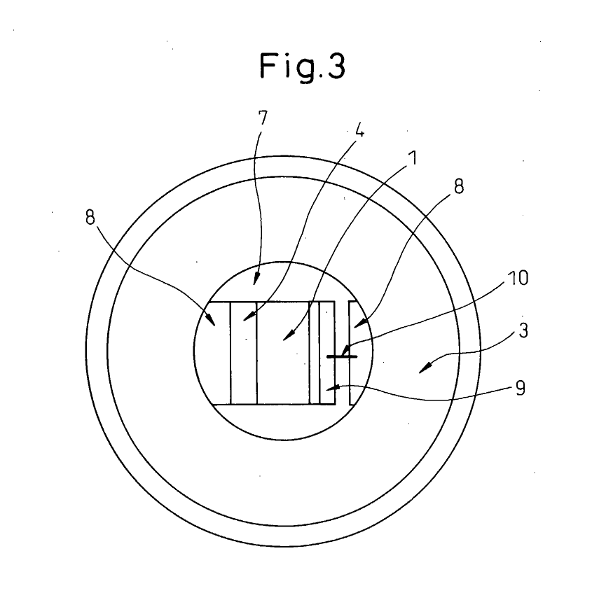

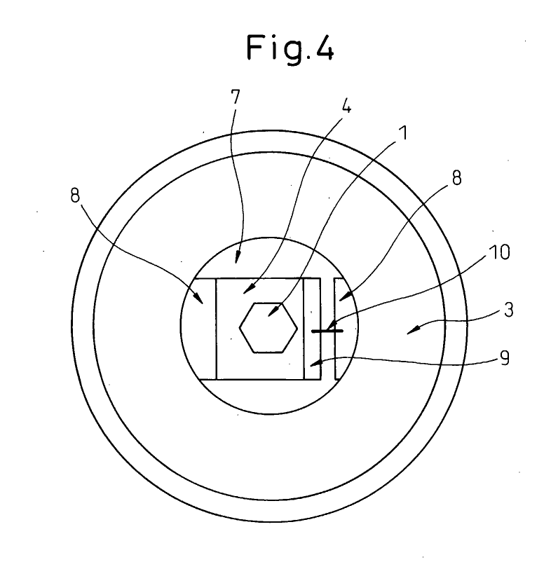

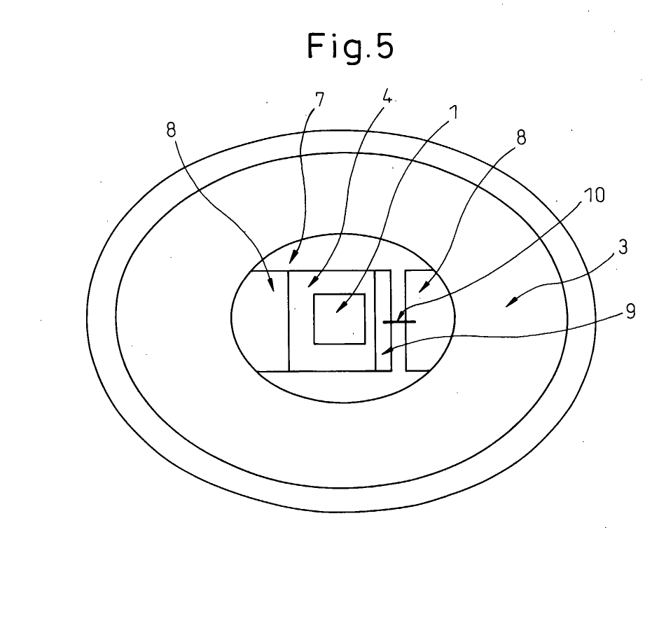

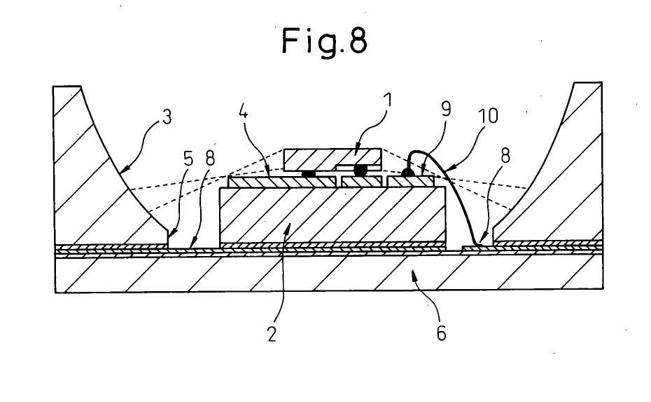

The present invention exhibits its effect when applied to the semiconductor light-emitting devices of a variety of combinations, such as “rectangular chip, sub-mount, circular reflector”, “polygonal chip, sub-mount, circular reflector” and “square chip, sub-mount, elliptic reflector” in addition the above combination of “square chip, sub-mount, circular reflector”. FIG. 3 is a plan view schematically illustrating a combination of “rectangular chip, sub-mount and circular reflector”, FIG. 4 is a plan view schematically illustrating a combination of “polygonal chip, sub-mount, circular reflector”, and FIG. 5 is a plan view schematically illustrating a combination of “square chip, sub-mount, elliptic reflector”. Further, FIG. 8 is a sectional view schematically illustrating a semiconductor light-emitting device of the invention when the side surface of the reflector is a parabolic surface.

### Comparative Example 1

A semiconductor light-emitting device was fabricated in the same manner as in Example 1 with the exception of setting the height of the sub-mount to be 100 μm. Therefore, the obtained semiconductor light-emitting device failed to satisfy the above formula (A). The obtained semiconductor light-emitting device was evaluated in the same manner as in Example 1. The whole emission flux was 140 mW when a forward current of 350 mA was supplied, and was inferior to that of the semiconductor light-emitting device of Example 1.

### Example 2

This embodiment deals with a face-up chip forming two electrodes on the surface of the semiconductor side. FIG. 9 is a sectional view schematically illustrating the semiconductor light-emitting device fabricated in this Example.

The semiconductor light-emitting device was fabricated in the same manner as in Example 1 but using a face-up chip as the semiconductor light-emitting element. The face-up chip was obtained according to the following procedure.

The procedure was the same as in Example 1 from when an epitaxially stacked layer structure of LED comprising a III-Group nitride compound semiconductor was formed on the sapphire substrate by using the MOCVD device until when it was dry-etched. A negative electrode of the light-emitting element was formed on the etched potion, a positive electrode comprising an ITO of a light-transmitting material of the light-emitting element was formed on the surface that has not been etched, and electrode pads for wire bonding were formed on a portion thereof. Au formed the uppermost surfaces of the electrode pads. Thereafter, the back surface of the sapphire substrate was ground and polished to a thickness of about 80 μm, and the wafer was divided into 1-mm square chips of the face-up type.

The sizes of the sub-mount, package and reflector were the same as those of Example 1 and their positional relationship satisfied the above formula (A). The thus obtained semiconductor light-emitting device was evaluated for its light-emitting output in the same manner as in Example 1. The whole emission flux was 140 mW when a forward current of 350 mA was supplied.

### Comparative Example 2

A semiconductor light-emitting device was fabricated in the same manner as in Example 2 with the exception of setting the height of the sub-mount to be 100 μm. Therefore, the obtained semiconductor light-emitting device failed to satisfy the above formula (A). The obtained semiconductor light-emitting device was evaluated in the same manner as in Example 1. The whole emission flux was 120 mW when a forward current of 350 mA was supplied, and was inferior to that of the semiconductor light-emitting device of Example 2.

### Example 3

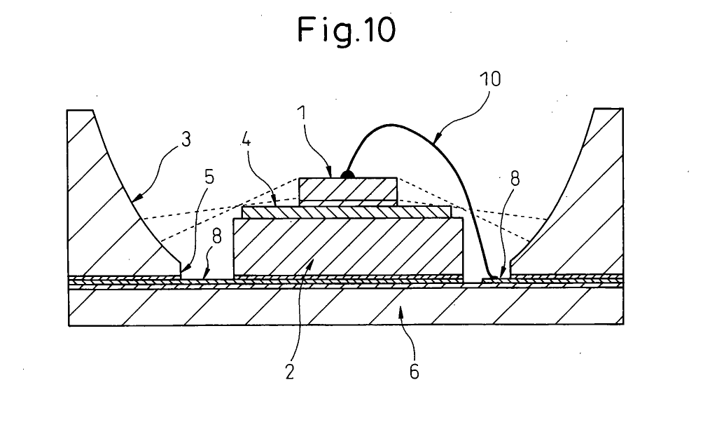

This embodiment deals with a face-up chip of the type having an electrode on the back surface side of the substrate. FIG. 10 is a sectional view schematically illustrating the semiconductor light-emitting device fabricated in this Example.

By using the MOCVD device, an epitaxially stacked layer structure of LED comprising a III-Group nitride compound semiconductor was formed on an SiC substrate in the same manner as in Example 1. The surface of the above epitaxial wafer was patterned so as to form a light-emitting element of a square of 1 mm relying upon the photolithography technology. A negative electrode of the light-emitting element was formed on the whole back surface of the SiC substrate, and circular positive electrodes were formed maintaining a pitch of 1 mm on part of the surface on where a III-Group nitride compound semiconductor has been epitaxially grown. Thereafter, the SiC substrate was cut by a dicer to form a 1-mm square chip of the type having an electrode on the back surface side of the substrate. The chip possessed a thickness of 400 μm. Therefore, the chip possessed hc=400 μm and 1c=500 μm.

The sub-mount possessed a size of hs=500 μm and is 1300 μm. The shape of the reflector was the same as that of Example 1 except that the side surfaces were parabolic surfaces, i.e., possessed d=100 μm and r=2000 μm. Therefore, the obtained semiconductor light-emitting device satisfied the above formula (A). The thus obtained semiconductor light-emitting device was evaluated for its light-emitting output in the same manner as in Example 1. The whole emission flux was 120 mW when a forward current of 350 mA was supplied.

### Comparative Example 3

A semiconductor light-emitting device was fabricated in the same manner as in Example 3 with the exception of setting the height of the sub-mount to be 100 μm. Therefore, the obtained semiconductor light-emitting device failed to satisfy the above formula (A). The obtained semiconductor light-emitting device was evaluated in the same manner as in Example 1. The whole emission flux was 80 mW when a forward current of 350 mA was supplied, and was inferior to that of the semiconductor light-emitting device of Example 3.

### INDUSTRIAL APPLICABILITY

The semiconductor light-emitting device of the invention features improved efficiency for providing light and a high light-emitting output, and can be very effectively used as, for example, a indictor and a large outdoor display, which are colored, and a source of back light for cell phones, a headlight and a source of light for illumination which emit white light, offering very great industrial value.

1. A semiconductor light-emitting device comprising a package substrate, a sub-mount provided on the package substrate, a semiconductor light-emitting element provided on the sub-mount, and a reflector surrounding the sub-mount and the semiconductor light-emitting element, wherein the positions and sizes of the sub-mount, light-emitting element and reflector satisfy the following relationship (A) on a cross section perpendicular to the package substrate that passes through the center of the semiconductor light-emitting element,
r−1s≦(hs−d)×(1s−1c)/hc (A)
wherein r, 1s and 1c are distances from the drooping portion of the reflector, from the outer circumference of the sub-mount and from the outer circumference of the semiconductor light-emitting element to the center of the semiconductor light-emitting element, respectively, hs and d are heights of the sub-mount and of the drooping portion of the reflector, respectively, and hc is a height of the upper surface of the semiconductor light-emitting element from the upper surface of the sub-mount.

2. The semiconductor light-emitting device according to claim 1, wherein the side surface of the reflector is a parabolic surface, and its focal point is a center of the semiconductor light-emitting element.

3. The semiconductor light-emitting device according to claim 1, wherein the semiconductor light-emitting element is of the face-up type.

4. The semiconductor light-emitting device according to claim 1, wherein the semiconductor light-emitting element is of the type having upper and lower electrodes on the top and bottom surfaces of the element.
